(19) United States
(12) Patent Application Publication
(10) Pub. No.: US 2026/0091974 A1
(43) Pub. Date: Apr. 2, 2026

(54) WAFER LEVEL PACKAGE FOR DEVICE

(71) Applicant: Teknologian tutkimuskeskus VTT Oy, Espoo (FI)

(72) Inventors: Jae-Wung Lee, Espoo (FI); Henri Ailas, Espoo (FI); Tuomas Pensala, Espoo (FI); Jukka Kyynäräinen, Espoo (FI)

(73) Assignee: Teknologian tutkimuskeskus VTT Oy, Espoo (FI)

(21) Appl. No.: 19/114,851

(22) PCT Filed: Sep. 21, 2023
(86) PCT No.: PCT/FI2023/050539

§ 371 Date: Mar. 25, 2025

(30) Foreign Application Priority Data
Sep. 27, 2022 (FI) 20225841

(51) Int. Cl. B81B 7/00; B81C 1/00

(52) U.S. Cl. CPC B81B 7/007; B81C 1/00269; B81C 1/00301; B81B 2207/097

(57) ABSTRACT

There is provided a wafer level package (100) for a device comprising: a first substrate (104) and a second substrate (116); at least one ground line (102) on a surface of the first substrate (104); at least one lateral electrical connection line (106) on the first substrate (104); a seal ring (108) between the first substrate (104) and the second substrate (116), wherein the at least one ground line (102) is terminated at the seal ring (108) and the at least one lateral electrical connection line (106) is configured to extend through the seal ring (108) for creating an electrical connection between the device inside the package (100) and an electrical circuit outside the package (100), and the seal ring comprises a passage (110) configured extend to the at least one ground line (102) through the seal ring (108); a bonding layer (122) between the seal ring (108) and the second substrate (116) for bonding the second substrate with the first substrate (104), wherein the bonding layer (122) is configured to connect the second substrate (116) to the at least one ground line (102).

### FIELD

The invention relates to a wafer level package for a device, in particular to a wafer level package for microelectromechanical systems (MEMS).

### BACKGROUND

Microelectromechanical systems (MEMS) are miniaturized mechanical and electro-mechanical elements, such as devices and structures that are made using the techniques of microfabrication. MEMS are comprised of components between 1 and 100 micrometers in size and MEMS devices generally range in size from 20 micrometers to a millimeter.

Due to their small size, composition and extremely demanding manufacturing methods, MEMS devices are susceptible to electrical failures and mechanical damages. Therefore, MEMS devices need to be packaged, for example by sealing the device between two wafers connected by a seal ring. However, sealing of the MEMS device can introduce electrical parasitic between signal lines and between signal lines and the ground line, therefore impairing the device's performance.

### SUMMARY OF THE INVENTION

The invention is defined by the features of the independent claims. Some specific embodiments are defined in the dependent claims.

### BRIEF DESCRIPTION OF THE DRAWINGS

FIG. 1 illustrates a part of a wafer level package in accordance with at least some embodiments of the present invention;

FIG. 2 illustrates an example of a seal ring in accordance with at least some embodiments of the present invention;

FIG. 3 illustrates a part of a wafer level package before bonding in accordance with at least some embodiments of the present invention;

FIG. 4 illustrates a lateral cross-section of the wafer level package of FIG. 3 after bonding in accordance with at least some embodiments of the present invention;

FIG. 5 illustrates a part of a wafer level package before bonding in accordance with at least some embodiments of the present invention;

FIG. 6 illustrates a lateral cross-section of the wafer level package of FIG. 5 after bonding in accordance with at least some embodiments of the present invention; and

FIG. 7 illustrates a method for forming a wafer level package for a device.

### EMBODIMENTS

The object of at least of some embodiments of the present invention is to provide a high quality wafer level package, especially for a microelectromechanical systems (MEMS) device, which mitigates electrical parasitic between signal lines and between signal lines and the ground line.

Identical or corresponding functional and structural elements which appear in the different drawings are assigned the same reference numerals. When the words first and second are used to refer to different elements, it is to be understood that this does not necessarily imply or mean that the first and second elements are somehow structurally substantially different elements or that their dimensions are substantially different unless specifically stated.

In the present context, the term “substrate” comprises a wafer, such as a MEMS device wafer and a cap wafer.

In the present context, a lateral direction may be a direction that is substantially parallel to a surface of a substrate. Therefore, in the following the term “lateral” is used to refer to the lateral direction or a direction substantially parallel with the lateral direction. In the following “laterally” is used to refer to a direction, i.e. the lateral direction or a direction substantially parallel with the lateral direction, where an object or item is observed or described.

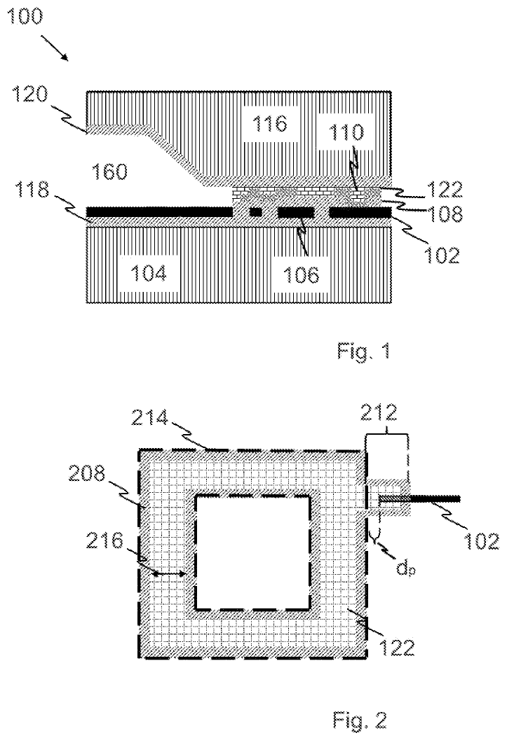

FIG. 1 illustrates a part of a wafer level package in accordance with at least some embodiments of the present invention. The wafer level package 100 for a device comprises a first substrate 104 and a second substrate 116, at least one ground line 102 on the first substrate, at least one lateral electrical connection line 106 on the first substrate and a seal ring 108 between the first substrate 104 and the second substrate 116. The at least one ground line 102 is terminated at the seal ring 108 and the at least one lateral electrical connection line 106 is configured to extend through the seal ring 108 for creating an electrical connection between the device inside the package 100 and an electrical circuit outside the package 100. The seal ring comprises a passage 110 configured extend to the at least one ground line 102 through the seal ring 108. The wafer level package 100 for a device comprises a bonding layer 122 between the seal ring 108 and the second substrate 116. The bonding layer 122 is configured to connect the second substrate 116 to the at least one ground line 102. Thus, the second substrate is grounded to the at least one ground line on the first substrate, whereby electrical parasitic is mitigated, while passage of fluid between the cavity 160 and outside of the wafer level package is prevented by the seal ring. Accordingly, the seal ring may serve for hermetically sealing the device inside the package. It should be noted that the wafer level package in FIG. 1 is illustrated after the device has been sealed inside the package, e.g. by a bonding process, where the bonding layer 122 is formed.

In an example, the wafer level package 100 may be formed by a bonding process that forms the bonding layer 122. The bonding layer may ground the second substrate 116, or a passivation layer 120 arranged on the second substrate, to the at least one ground line 102 through the passage 110. It should be noted that before the bonding of the first substrate with the second substrate, the substrates are separate from each other. However, the bonding process joins the first substrate with the second substrate, whereby the device is sealed within the wafer level package.

In an example, the wafer level package 100 may comprise a cavity 160 for accommodating the device and the at least one lateral electrical connection line 106 on the surface of the first substrate is arranged to travel in a direction substantially parallel with facing surfaces of the first substrate and the second substrate 116 for creating the electrical connection between the device inside the package 100 and an electrical circuit outside the package 100.

In an example in accordance with at least some embodiments, the bonding layer 122 comprises an inter-metallic compound. The inter-metallic compound provides electrical conductivity for grounding the second substrate.

In an example in accordance with at least some embodiments, the inter-metallic compound comprises a metal alloy, for example a eutectic metal alloy.

In an example, the bonding layer is formed by a bonding process. In an example, the bonding process comprises forming an inter-metallic compound, for example a eutectic metal alloy. The metal alloy may be formed by at least two bonding materials.

Examples of bonding processes comprise at least eutectic bonding and transient liquid phase bonding. Eutectic bonding may comprise heating a first bonding material layer formed on a surface of the seal ring and a second bonding material formed on a surface of the second substrate to their melting points, whereby the bonding materials change completely into liquid at the same temperature and the intermetallic compound is formed. The intermetallic compound is solidified once the temperature drops below the melting points of the metals. On the other hand, the inter-metallic compound may be formed by the transient liquid phase bonding, wherein lower temperatures than the bonding temperatures of the most usual eutectic alloys may be used. Thus, the transient liquid phase bonding can be used to provide the inter-metallic compound bonding layer in applications where lower temperatures are needed. The transient liquid phase bonding is an advanced type of solder bonding process which can form high-quality hermetic seals at lower temperatures than other bonding technologies. The transient liquid phase bonding uses one thin layer of metal (typically 1-10 pm thick) which during a thermal process diffuses into its bonding partner forming an inter-metallic compound layer with re-melting temperature higher than the bonding temperature.

In an example in accordance with at least some embodiments, a first passivation layer 118 is arranged on a surface of the first substrate 104 and/or a second passivation layer 120 is arranged on a surface of the second substrate 116. The passivation layer(s) mitigate electrical coupling of the first substrate and the second substrate with the at least one lateral electrical connection line 106 and the at least one ground line 102. In an example, the passivation layer may be dielectric film or an insulator film. An example of the dielectric film is an SiO₂ film. Examples of insulator films comprise metal oxide films comprising TiO₂ or Al₂O₃.

In an example in accordance with at least some embodiments, the seal ring 108 comprises a first seal ring portion 302 and a second seal ring portion 304 configured to provide lateral separation between the at least one lateral electrical connection line 106 and the at least one ground line 102. In this way electrical parasitic between the at least one ground line and electrical connection lines may be mitigated. In an example the first seal ring portion 302 may be arranged on the at least one lateral electrical connection line 106 and the second seal ring portion 304 may be arranged on the at least one ground line 102. In this way the at least ground line and the at least one electrical connection line are located at laterally separate portion of the seal ring.

In an example in accordance with at least some embodiments, the first seal ring portion 302 and the second seal ring portion 304 are separated from each other laterally by the bonding layer 122. In this way the electrical parasitic between the at least one ground line and electrical connection lines may be further mitigated.

In an example in accordance with at least some embodiments, the wafer level package 100 is for a MEMS device.

FIG. 2 illustrates an example of a seal ring in accordance with at least some embodiments of the present invention. The seal ring 208 is illustrated by a lateral cross-section of the seal ring 108 of the wafer level package of FIG. 1 and the bonding layer 122 on top of the seal ring. The bonding layer provides that the second substrate 116, e.g. a cap wafer can be connected to the at least one ground line, or grounded, via the bonding layer for mitigating electrical parasitic.

In an example in accordance with at least some embodiments, the seal ring 208 comprises a first seal ring portion 214 and a second seal ring portion 212 configured to provide lateral separation between the at least one lateral electrical connection line 106 and the at least one ground line 102.

In an example in accordance with at least some embodiments, the seal ring 208 comprises a ring-like body 214 and an extension 212 protruding laterally outwards from the ring-like body 214. The extension 212 provides that that the at least one ground line may be terminated at a distance dₚ from the ring-like body. In this way, electrical parasitic between electrical signal lines travelling at the ring-like body and the at least one ground line may be mitigated.

In an example, a width 216 of the seal ring 208 in a cross-sectional direction, i.e. laterally through the seal ring, can be for example, 40-300 μm, such as 60-100 μm.

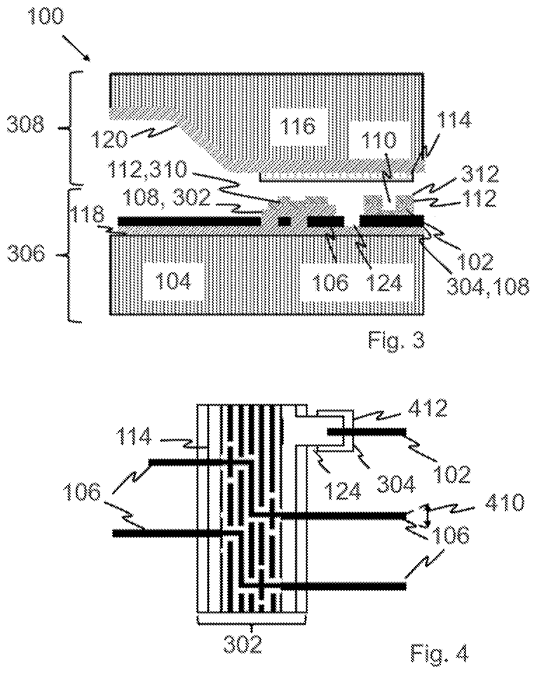

FIG. 3 illustrates structures for forming a wafer level package in accordance with at least some embodiments of the present invention. The structures may be used for forming a wafer level package. The structures are described with reference to items described with FIG. 1. The structures are illustrated before the structures are bonded together by a bonding process that forms the bonding layer 122 for joining the substrates of the wafer level package together. The structures comprise a first structure 306 comprising the first substrate 104 and a second structure 308 comprising the second substrate 116. The first structure may comprise a bonding material layer 112, e.g. a first bonding material layer. The second structure may comprise a bonding material layer 114, e.g. a second bonding material layer. The first bonding material layer may be arranged on the seal ring 108. The second bonding material layer may be arranged on the second substrate 116. The wafer level package 100 may be formed from the structures 306, 308 by a bonding process of the first structure and the second structure, whereby the second substrate 116 is grounded to the at least one ground line 102 through the passage 110 by an inter-metallic compound formed by the first bonding material layer 112 and the second bonding material layer 114. Accordingly, before the bonding process, the substrates are separate from each other. However, the bonding process joins the first substrate with the second substrate, whereby the device is sealed within the wafer level package and the second substrate is grounded for mitigating electrical parasitic.

In an example, the bonding layer 122 may be formed by eutectic bonding of bonding material layers 112, 114, wherein bonding materials of the bonding material layers mix and form an intermetallic compound that compresses into shape. In this way the bonding material layer 122 is created. In an example, a thickness of the bonding material layer 122 may be smaller than a combined thickness of the bonding material layers 112, 114 and the thickness of the bonding material layer 122 may be equal to or greater than a thickness of the electrical connection line 106. In an example, the bonding material layer 112 may be of Al and have a thickness of 500 nm-900 nm. In an example, the bonding material layer 114 may be of Ge and have a thickness of 300 nm-500 nm. On the other hand, the bonding material layer 114 may be of Al and have a thickness of 500 nm-900 nm and the the bonding material layer 112 may be of Ge and have a thickness of 300 nm-500 nm.

FIG. 4 illustrates the seal ring 108 illustrated in FIG. 3 as seen from above the second bonding material layer 114. One or more lateral electrical connection lines 106 extend through the seal ring 108 for creating an electrical connection between the device inside the package 100. The electrical connection lines 106 travel through the first seal ring portion 302 and the at least one ground line 102 is terminated at the second seal ring portion 304. In this way the device inside the wafer level package may be connected by the electrical connection lines. In an example, a width 410 of a lateral electrical connection line 106 that connects the device inside the package with the electrical circuit outside the package may be for example, 5-30 pm, such as 10-20 pm.

In an example in accordance with at least some embodiments, the seal ring 108 comprises a first seal ring portion 302 and a second seal ring portion 304 and the second seal ring portion is laterally separated from the first seal ring portion by a gap 124. It should be noted that at the bonding process, the gap may be filled by the bonding layer 122.

In an example in accordance with at least some embodiments, the first structure comprises the first bonding material layer 112 arranged on a surface of the seal ring 108 and the first bonding material layer 112 comprises at least two portions 310, 312 that form separate areas on the surface of the seal ring. In an example, a first portion 310 of the first bonding material layer may be laterally separated from a second portion 312 of the first bonding material layer. In an example, the first portion 310 may be arranged on a first portion 302 of the seal ring 108 comprising one or more electrical connection lines 106 configured to extend through the seal ring 108 for creating an electrical connection between the device inside the package 100. In an example, the second portion 312 may be arranged on a second portion 304 of the seal ring 108 comprising the at least one ground line 102. Accordingly, the least two portions 310, 312 may be separated by a gap 124 for lateral separation of the least two portions 310, 312.

In an example in accordance with at least some embodiments, the at least one electrical connection line and the at least one ground line may be laterally separated by a gap 124. Additionally, the gap may laterally separate the portions of the seal ring 310, 312 from each other.

In an example in accordance with at least some embodiments, the first structure 306 comprises that the first bonding material layer 112 arranged on the seal ring 108 is adapted to a shape of the passage 110. In an example, the first bonding material layer may extend from a surface of the seal ring 108 facing the second substrate, away from the second substrate, along inner wall(s) of the passage, and to the at least one ground line 102. In this way, at bonding of the structures 308,306 the first bonding material is present inside the passage, whereby the bonding layer 122 may be formed from the first bonding material layer 112 and the second bonding material layer 114. For example, during a bonding process, the fist bonding material of the first bonding material layer 112 and the second bonding material of the second bonding material layer 114 may transform into liquid phase, whereby the second boning material may flow into the passage for forming an intermetallic compound of the first bonding material and the second bonding material.

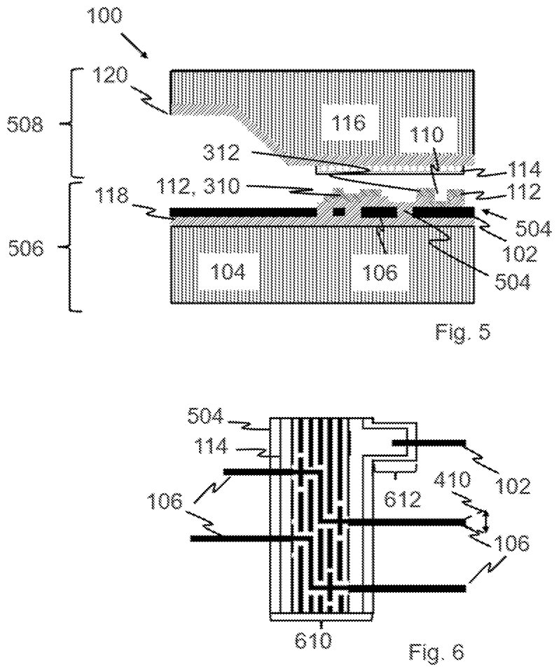

FIG. 5 illustrates structures for forming a wafer level package in accordance with at least some embodiments of the present invention. The structures 506,508 are described with reference to items described with FIG. 1, FIG. 3 and FIG. 4. The structures 506,508 may be in accordance with at least part of the structures 306,308 described with FIG. 3 and FIG. 4. The structures 506,508 are illustrated before the structures are bonded together by a bonding process that forms a bonding layer for joining substrates of a wafer level package similar to described with FIG. 1. As a difference to FIG. 3, in FIG. 4, in FIG. 5 the first structure 506 comprises a seal ring 504 that comprises a single laterally extending portion configured to extend on both the at least one lateral electrical connection line 106 and on the at least one ground line 102. Accordingly the at least one lateral electrical connection line 106 and the at least one ground line 102 are interconnected by the seal ring without a gap 124 in the seal ring between the at least one lateral electrical connection line 106 and the at least one ground line 102. However, it should be noted that although the seal ring 504 does not comprise the gap 124, a lateral space between the at least one ground line and the at least one electrical connection line is filled by the seal ring, whereby lateral separation of the at least one ground line and the at least one electrical connection line is supported.

FIG. 6 illustrates the seal ring 504 illustrated in FIG. 5 as seen from above the second bonding material layer 114. One or more lateral electrical connection lines 106 extend through the seal ring 504 for creating an electrical connection between the device inside the wafer level package. The lateral electrical connection lines 106 travel through a first seal ring portion 610 and the at least one ground line 102 is terminated at a second seal ring portion 612. In this way the seal ring is configured to provide lateral separation between the electrical connection lines and the at least one ground line.

In an example in accordance with at least some embodiments, the seal ring 504 comprises a first portion 610, e.g. a ring-like body, and a second portion that is an extension protruding laterally outwards from the ring-like body. In this way lateral separation between the at least one electrical connection line and a ground line may be provided.

In an example in accordance with at least some embodiments, the seal ring 504 comprises a single continuous laterally extending layer configured to extend on both the at least one lateral electrical connection line 106 and on the at least one ground line 102. Accordingly the at least one lateral electrical connection line 106 and the at least one ground line 102 are interconnected by the seal ring without a gap 124 in the seal ring between the at least one lateral electrical connection line 106 and the at least one ground line 102. Therefore, it should be note that the single continuous laterally extending layer may connect laterally portions of the seal ring.

In an example the seal ring 108, 504 may comprise dielectric material for example silicon dioxide (SiO2), aluminum nitride (AlN), aluminum oxide (Al2O3), silicon nitride (Si3N4) or silicon carbide (SiC). These substances provide a good wetting surface for a bonding layer and a good electric insulation.

In an example in accordance with at least some embodiments, the bonding layer 122 is an inter-metallic compound. The inter-metallic compound may comprise a eutectic metal alloy, such as, germanium-aluminum, gold-tin, gold-germanium, gold-silicon, gold-indium or copper-tin alloy, copper-tin, gold-indium or silver-tin alloy.

In an example in accordance with at least some embodiments, the bonding material layer 112, 114 may comprise bonding material for example germanium, aluminum, gold, tin, silicon, indium, copper or silver.

In an example, the first substrate 104 and the second substrate 116 comprise silicon or ceramic. Silicon is very reliable substrate material as it suffers very little fatigue and can have long service lifetimes without breaking. In single crystal form, silicon has virtually no hysteresis and hence almost no energy dissipation. Suitable ceramic substrates are, for example, silicon nitride, aluminum nitride, titanium nitride or silicon carbide. Aluminum nitride in the wurtzite structure shows pyroelectric and piezoelectric properties, which enables to produce sensors for example, with sensitivity to normal and shear forces. Titanium nitride exhibits a high electrical conductivity and large elastic modulus.

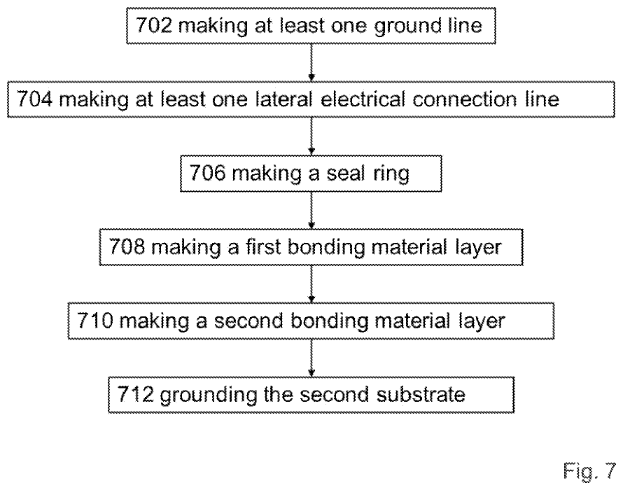

FIG. 7 illustrates a method for forming a wafer level package for a device. The phases of the method may form structures described in FIG. 3 and FIG. 5 for forming the wafer level package.

Phase 702 comprises making at least one ground line on a surface of a first substrate.

Phase 704 comprises making at least one lateral electrical connection line 106 on the surface of the first substrate.

Phase 706 comprises making a seal ring on the surface of the first substrate, wherein the at least one ground line on the surface of the first substrate is terminated at the seal ring and the at least one lateral electrical connection line 106 on the surface of the first substrate extends through the seal ring for creating an electrical connection between the device inside the package and an electrical circuit outside the package, and the seal ring comprises a passage configured extend to the at least one ground line through the seal ring.

Phase 708 comprises making a first bonding material layer on the surface of the seal ring.

Phase 710 comprises making a second bonding material layer on a surface of a second substrate.

Phase 712 comprises grounding the second substrate to the at least one ground line through the passage by a bonding layer formed by the first bonding material layer and the second bonding material layer.

In an example, phase 712 comprises forming the bonding layer by a bonding process. In an example, the bonding process comprises forming an inter-metallic compound, for example a eutectic metal alloy. The metal alloy may be formed by at least two bonding materials.

In an example, phase 712 comprises bonding the first substrate 104 with the second substrate 116 by a bonding process, for example eutectic bonding or transient liquid phase bonding, whereby a bonding layer is formed. In eutectic bonding, temperature can be first raised to a value lower than the eutectic temperature of the eutectic alloy. Then, temperature can be maintained constant for short time to reach uniform heating of both first substrate and second substrate. After that, temperature can be increased to a temperature exceeding the eutectic point. Finally, the structure can cool down to a temperature below the eutectic temperature.

In an example, phases 702 and 704 comprise separating the at least one electrical connection line and the at least one ground line by a gap 124, or space. The gap may be provided by an arrangement of the at least one electrical connection line and the at least one ground line. Additionally the gap may separate laterally portions of the seal ring.

In an example, phase 706 comprises depositing material for forming the seal ring on the first substrate and making, e.g. by silicon wet or dry etching, one or more trenches to the deposited seal ring. In an example a trench may laterally separate a first seal ring portion from a second seal ring portion, whereby the seal ring comprising more than one portions may be formed. In an example, the passage may be formed by etching.

In an example phase 708 and/or phase 710 comprises depositing bonding material on a surface of the substrate, wherein the bonding material comprises germanium, aluminum, gold, tin, silicon, indium, copper or silver.

In an example in accordance with at least some embodiments, phase 702 comprises making a first passivation layer on the surface of the first substrate and/or phase 704 comprises making a second passivation layer on the surface of the second substrate. The passivation layer can be grown by thermal oxidation in which a layer is exposed to oxygen and/or steam to grow a thin surface layer on the layer.

In an example in accordance with at least some embodiments, phase 708 comprises forming the first bonding material layer comprising at least two portions on the surface of the seal ring.

In an example in accordance with at least some embodiments phase 706 comprises: forming the seal ring comprising a first seal ring portion separated laterally by a gap from a second seal ring portion; or forming the seal ring comprising a single laterally extending portion configured to extend on both the at least one lateral electrical connection line 106 and on the at least one ground line.

In an example in accordance with at least some embodiments phase 706 comprises filling, by the seal ring, a lateral space between the at least one ground line and the at least one electrical connection line. In this way lateral separation of the at least one ground line and the at least one electrical connection line is supported by the seal ring. It should be noted that the space may be provided at least by an arrangement of the at least electrical connection line and the at least one ground line.

In an example in accordance with at least some embodiments phase 706 comprises forming the first bonding material layer comprising at least two portions on the surface of the seal ring.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the following description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, i.e. a singular form, throughout this document does not exclude a plurality.

### REFERENCE SIGNS LIST

100 wafer level package
102 ground line
106 electrical connection line
108 seal ring
110 passage
112, 114 bonding material layer
104, 116 substrate
118, 120 passivation layer
122 bonding layer
124 gap
208 seal ring
212,214 seal ring portion
216 width of seal ring in a cross-sectional direction
302, 304 seal ring portions
306, 308 structures for wafer level package
310, 312 portions of bonding material layer
504 seal ring
506, 508 structures for wafer level package
610, 612 seal ring portions
dₚ distance from the ring-like body

1. A wafer level package (100) for a device comprising:
a first substrate (104) and a second substrate (116);
at least one ground line (102) on a surface of the first substrate (104);
at least one lateral electrical connection line (106) on the first substrate (104);
a seal ring (108) between the first substrate (104) and the second substrate (116), wherein the at least one ground line (102) is terminated at the seal ring (108) and the at least one lateral electrical connection line (106) is configured to extend through the seal ring (108) for creating an electrical connection between the device inside the package (100) and an electrical circuit outside the package (100), and the seal ring comprises a passage (110) configured to extend to the at least one ground line (102) through the seal ring (108);
a bonding layer (122) between the seal ring (108) and the second substrate (116) for bonding the second substrate with the first substrate (104), wherein the bonding layer (122) is configured to connect the second substrate (116) to the at least one ground line (102).

2. The wafer level package according to claim 1, wherein the bonding layer (122) comprises an inter-metallic compound.

3. The wafer level package according to claim 2, wherein the inter-metallic compound comprises a metal alloy, for example a eutectic metal alloy.

4. The wafer level package according to claim 1, wherein the seal ring (108) comprises a first seal ring portion and a second seal ring portion configured to provide lateral separation between the at least one lateral electrical connection line (106) and the at least one ground line (102).

5. The wafer level package according to claim 4, wherein the first seal ring portion is on the at least one lateral electrical connection line (106) and the second seal ring portion is on the at least one ground line (102).

6. The wafer level package according to claim 4, wherein the first seal ring portion and the second seal ring portion are separated from each other laterally by the bonding layer (122).

7. The wafer level package according to claim 1, wherein the seal ring comprises a ring-like body and the second seal ring portion is an extension protruding laterally outwards from the ring-like body or the second seal ring portion is laterally separated from the ring-like body by a gap.

8. The wafer level package according to claim 1, wherein the seal ring (108) comprises:
a single laterally extending portion configured to extend on both the at least one lateral electrical connection line (106) and on the at least one ground line (102).

9. The wafer level package according to claim 1, comprising:
a first passivation layer (118) on a surface of the first substrate (104) and/or a second passivation layer (120) on a surface of the second substrate (116).

10. The wafer level package according to claim 1, wherein the wafer level package (100) is for a MEMS device.

11. A method for forming a wafer level package (100) for a device comprising:
making at least one ground line (102) on a first substrate (104);
making at least one lateral electrical connection line (106) on the first substrate (104);
making a seal ring (108) on the first substrate (104), wherein the at least one ground line (102) on the first substrate is terminated at the seal ring (108) and the at least one lateral electrical connection line (106) extends through the seal ring (108) for creating an electrical connection between the device inside the package (100) and an electrical circuit outside the package (100), and the seal ring comprises a passage (110) configured to extend to the at least one ground line (102) through the seal ring (108);
making a first bonding material layer (112) on the seal ring (108);
making a second bonding material layer (114) on a second substrate (116);
grounding the second substrate (116) to the at least one ground line (102) through the passage

(110) by a bonding layer (122) formed by the first bonding material layer (112) and the second bonding material layer (114).

12. The method according to claim 11, comprising:
forming the seal ring comprising a first seal ring portion separated laterally by a gap from a second seal ring portion, or
forming the seal ring (108) comprising a single laterally extending portion configured to extend on both the at least one lateral electrical connection line (106) and on the at least one ground line (102).

13. The method according to claim 11, comprising:
filling, by the seal ring, a lateral space between the at least one ground line and the at least one electrical connection line.

14. The method according to claim 11, comprising:
forming the first bonding material layer (112) comprising at least two portions on the surface of the seal ring (108).

15. The method according to claim 11, comprising:
making a first passivation layer (118) on a surface of the first substrate (104) and/or
making a second passivation layer (120) on a surface of the second substrate (116).
